(19) United States
(12) Patent Application Publication
(10) Pub. No.: US 2026/0343847 A1
(43) Pub. Date: Oct. 29, 2026

(54) TWO TRANSISTOR MEMORY ARCHITECTURE AND METHOD OF MANUFACTURING THE SAME

(71) Applicant: Taiwan Semiconductor Manufacturing Company, Ltd., Hsinchu (TW)

(72) Inventors: Kuo-Chang Chiang, Hsinchu City (TW); Chih-Yu Chang, New Taipei City (TW); Ming-Yen Chuang, Hsinchu City (TW); Tsung-Han Wu, New Taipei City (TW); Yi-Lin Yang, New Taipei City (TW)

(21) Appl. No.: 19/192,419

(22) Filed: Apr. 29, 2025

(51) Int. Cl. H10B 12/00

(52) U.S. Cl. CPC H10B 12/00

(57) ABSTRACT

In some embodiments, the present disclosure relates to an integrated device, including: a write gate over a substrate having a longest dimension in a first direction normal to a surface of the substrate; a write gate dielectric surrounding outer sidewalls of the write gate; a write channel layer surrounding outer sidewalls of the write gate dielectric; a read gate dielectric having a shortest dimension in the first direction and surrounding the write channel layer in a second direction and a third direction, the second direction and the third direction being perpendicular to the first direction; and a read channel layer having a longest dimension in the first direction, wherein a shortest path between the write channel layer and the read channel layer extends through the read gate dielectric.

### BACKGROUND

Integrated devices include a variety of memory types and structures to store data for different periods of time. Memory types used to store data for sort term usage include different types of random access memory (RAM), such as dynamic RAM (DRAM) and static RAM (SRAM). SRAM uses six transistors per memory cell to store and read information by altering and reading the state of latching circuitry, while DRAM uses less than six transistors and stores data by altering a stored charge. Read operations in DRAM devices determine the data stored in the cell by performing operations that are altered by the amount of stored charge.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIGS. 1A, 1B, 1C, and 1D illustrate a cross-sectional view and top down views of some embodiments of an integrated device having a memory cell with a two transistor architecture.

FIG. 2 illustrates a circuit diagram of some embodiments of an integrated device having the memory cell with the two transistor architecture.

FIGS. 3A and 3B illustrate a cross-sectional view and a top down view of some embodiments of the integrated device having the memory cell with the two transistor architecture with bit lines and words lines of uniform widths.

FIGS. 4A, 4B, 5A, 5B, 6A, 6B, 7A, 7B, 8A, 8B, 9A, 9B, 10A, 10B, 11A, 11B, 12A, 12B, 13A, 13B, 14, 15A, and 15B illustrate cross-sectional views of some embodiments of a method of forming an integrated device having the memory cell with the two transistor architecture.

FIG. 16 illustrates a flow diagram of some embodiments of a method of forming an integrated device having the memory cell with the two transistor architecture.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

Memory arrays are used in a wide variety of integrated devices, including image sensors, long term storage, short term cache and random access memory (RAM), or the like. Memory arrays store bits of data in memory cells of the memory arrays. The bits of data are stored as states of latching circuitry in static RAM (SRAM) circuits, and as states of charge in dynamic RAM (DRAM) circuits. Some embodiments of SRAM circuits use six transistors to form a latching circuit for a memory cell to store readable data. Some embodiments of DRAM circuits utilize one transistor and one capacitor in a memory cell to store readable data. DRAM circuits using less components results in a higher storage density compared to SRAM circuits. However, as the state of the DRAM memory cell is based on a charge stored at the capacitor, leakage through the capacitor or transistor may result in uncertainty or loss of the stored data.

Two transistor (2T0C) DRAM cells have been proposed to improve the retention time (e.g., time until leakage renders the reading of the stored data unreliable) of the memory cell. The charge is stored at a gate of the read transistor and is coupled to a source/drain region of the write transistor, resulting in the state of the read transistor depending on the charge stored, and reliable writing of new data being performed by activating the write transistor. However, the use of planar transistors in 2T0C DRAM cells results in a single memory cell having a larger area than the area used by some embodiments of one transistor, one capacitor (1T1C) DRAM cells.

Further, the concurrent formation of the channel, dielectric, and gates of the planar transistors results in reduced opportunities for optimization of the write and read transistors for their role. For example, the write transistor's ability to write a storage state accurately is based on the threshold voltage of the write transistor, which itself depends on the properties of the corresponding channel and gate dielectric. Similarly, the read transistor's ability to reliably read the storage state and reduce gate leakage depends on the properties of the corresponding channel and gate dielectric. When the channels and gate dielectrics of the write and read transistors are formed concurrently, the ability to optimize the write transistor and the read transistor for different roles is impaired.

In the present disclosure a 2T0C memory cell for a DRAM memory array is presented. A write transistor extends vertically between a first bit line and a first word line. A read transistor extends vertically between a second bit line and a second word line. A write channel layer of the write transistor surrounds the write gate of the write transistor, and a portion of the write channel layer functions as a read gate for the read transistor. A write gate dielectric separates the write gate from the write channel layer. A read channel layer is laterally separated from the write channel layer by a read gate dielectric. The read gate dielectric extends horizontally over the first bit line and the second bit line, surrounding the write channel layer and the read channel layer. The write gate dielectric and the read gate dielectric are formed independently of one another, resulting in greater flexibility in in selecting the thickness and composition of the write and read gate dielectric. The dimensions of openings that the write channel layer and the read channel layer are formed in changes the thickness of the read channel layer, resulting in a greater flexibility in selection of the thickness of the write and read channel layers. Further, the write channel layer is subject to an oxygen treatment that the read channel layer is insulated from, resulting in further differentiation between a carrier concentration of the write and read channel layers and further optimization of the parameters of the write and read transistor for their different purposes. The use of vertical transistors reduces the area in the integrated device by a memory cell, combining the reduced area of the 1T1C memory cell, the greater retention time of the 2T0C memory cell, and improved performance beyond that of a 2T0C memory cell utilizing planar transistors.

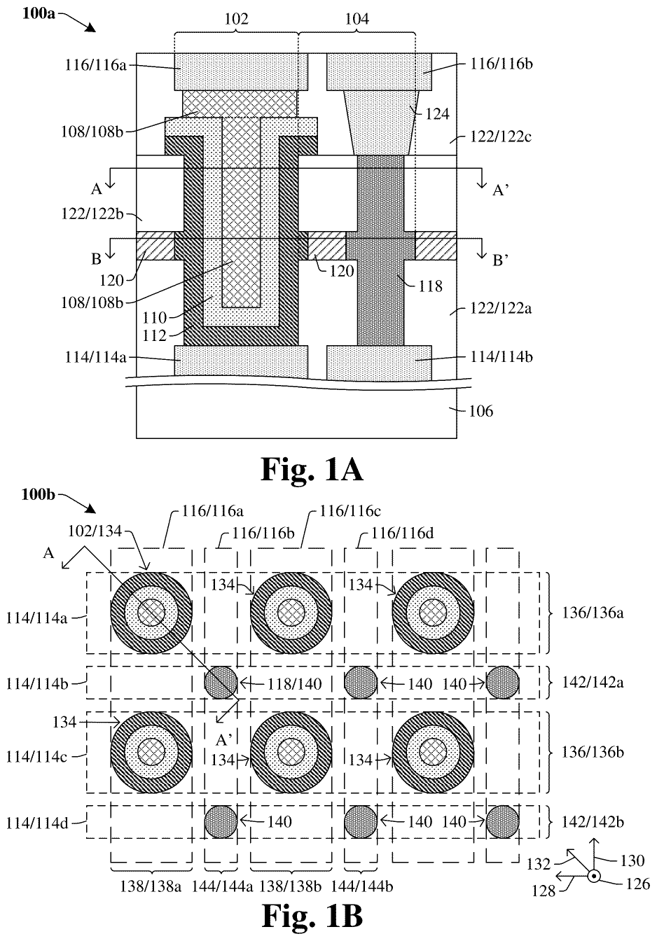

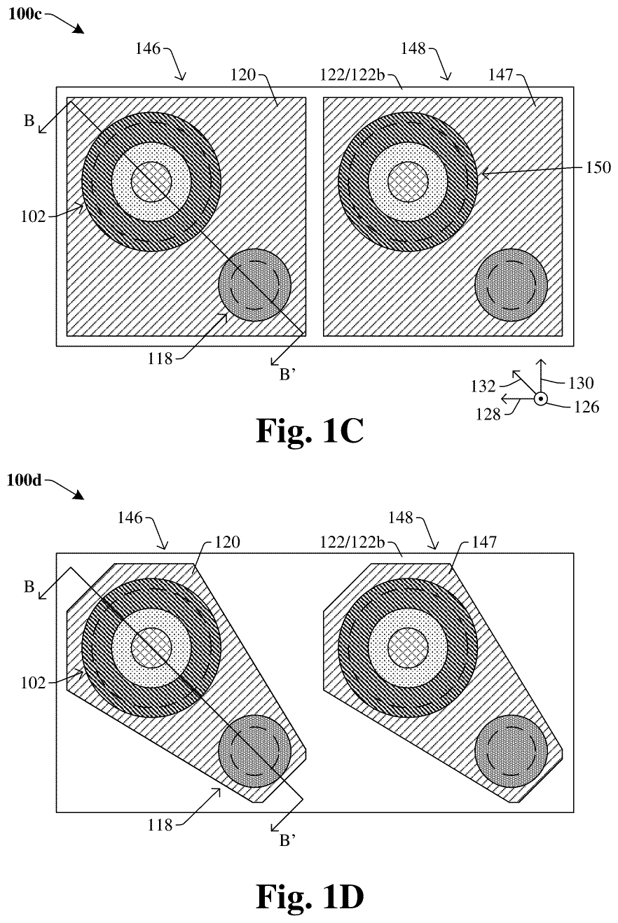

FIGS. 1A, 1B, 1C, and 1D illustrate a cross-sectional view 100a and top down views 100b, 100c, 100d of some embodiments of an integrated device having a memory cell with a two transistor architecture. FIG. 1A is taken along lines A-A′ of FIG. 1B and B-B′ of FIG. 1C. FIG. 1D shows an alternative embodiment to FIG. 1C.

A write transistor 102 and a read transistor 104 overly a substrate 106. The write transistor 102 comprises a write gate 108 with a base portion 108a and a protrusion portion 108b, a write gate dielectric 110 surrounding the protrusion portion 108b of the write gate 108, and a write channel layer 112 surrounding the write gate dielectric 110. The write channel layer 112 is electrically coupled to a first bit line 114a of a plurality of bit lines 114, and the write gate 108 is electrically coupled to a first word line 116a of a plurality of word lines 116.

A read channel layer 118 extends from a second bit line 114b of the plurality of bit lines 114 to a second word line 116b of the plurality of word lines 116. The read channel layer 118 is spaced from the write channel layer by a read gate dielectric 120. The read gate dielectric 120 surrounds the write channel layer 112 and the read channel layer 118. The read gate dielectric 120 is separated from the plurality of bit lines 114 by a first portion 122a of an interlayer dielectric 122. Further, the read gate dielectric 120 is separated from the plurality of word lines 116 by a second portion 122b of the interlayer dielectric 122. In some embodiments, a third portion 122c of the interlayer dielectric 122 surrounds the base portion 108a of the write gate 108 and a via 124 extending from the second word line 116b to the read channel layer 118.

The write channel layer 112 has a first thickness and a first oxygen density, and the read channel layer 118 has a second thickness and a second oxygen density. The second thickness is equal to or greater than the first thickness, and the first oxygen density is equal to or greater than the second oxygen density. In some embodiments, a ratio of the second thickness to the first thickness is 1, approximately 3, or a number between 1 and 3. Further, the write gate dielectric 110 has a thickness extending between the write gate 108 and the write channel layer 112, and the read gate dielectric 120 has a first minimum distance between the write channel layer 112 and the read channel layer 118. The thickness of the write gate dielectric 110 is equal to or less than the first minimum distance of the read gate dielectric 120. In some embodiments, a ratio of the thickness of the write gate dielectric 110 to the first minimum distance of the read gate dielectric 120 is 1, approximately 5, or a number between 1 and 5. In some embodiments, the first minimum distance extends along the shortest path between the write channel layer 112 and the read channel layer 118 (e.g., the shortest distance between the boundary of the write channel layer 112 and the boundary of the read channel layer 118).

The configuration of the write transistor 102 extending vertically from the first bit line 114a to the first word line 116a combined with the read channel layer 118 extending vertically from the second bit line 114b to the second word line 116b results in the write transistor 102 and the read transistor 104 having a smaller area than planar transistors, reducing the area of the memory cell. Further, the differences between the thickness and composition of the write and read channel layers 112, 118 and the write and read gate dielectric 110, 120 result in a 2T0C memory cell with improved performance and retention time. For example, a current density of the read channel layer 118 while the read transistor 104 is active is based in part on the thickness and oxygen density of the read channel layer 118, with a greater thickness and lower oxygen density resulting in a greater carrier concentration and a greater current density. Further, maintaining a positive voltage threshold for the write transistor 102 is in part based on the thickness and oxygen density of the write channel layer 112, with a lower thickness and a higher oxygen density reducing the carrier concentration of the channel, thereby increasing the voltage threshold of the write transistor 102.

As shown in the top down view 100b of FIG. 1B, the write transistor 102 and the read channel layer 118 extend in a first direction 126 from the plurality of bit lines 114 towards the plurality of word lines 116. The plurality of bit lines 114 extend in a second direction 128 perpendicular to the first direction 126. In some embodiments, the plurality of word lines 116 extend in a third direction 130 perpendicular to the first direction 126 and approximately perpendicular to the second direction 128. In other embodiments, the plurality of word lines 116 extend in a third direction 130 perpendicular to the first direction 126 and greater than or less than approximately perpendicular (e.g., approximately 60 degrees, approximately 135 degrees, or the like) to the second direction 128. The read channel layer 118 is laterally separated from the write transistor 102 in a fourth direction 132 between the second direction 128 and the third direction 130. In some embodiments, the fourth direction is approximately midway between (e.g., approximately 45 degrees from) the second direction 128 and the third direction 130.

The write transistor 102 is one transistor of an array of write transistors 134 extending in a first plurality of rows 136 and a first plurality of columns 138. The first plurality of rows 136 individually overly alternating bit lines (e.g., odd numbered bit lines counting sequentially from the first bit line 114a) of the plurality of bit lines 114. For example, a first row 136a of the first plurality of rows 136 directly overlies the first bit line 114a, a second row 136b of the first plurality of rows 136 directly overlies the third bit line 114c, and so on. The first plurality of columns 138 individually underly alternating word lines (e.g., odd numbered word lines counting sequentially from the first word line 116a) of the plurality of word lines 116. For example, a first column 138a of the first plurality of columns 138 directly overlies the first word line 116a, a second column 138b of the first plurality of columns 138 directly overlies the third word line 116c, and so on.

The read channel layer 118 is one channel layer of an array of read channel layers 140 extending in a second plurality of rows 142 and a second plurality of columns 144. The second plurality of rows 142 individually overly alternating bit lines (e.g., even numbered bit lines counting sequentially from the first bit line 114a) of the plurality of bit lines 114. For example, a first row 142a of the second plurality of rows 142 directly overlies the second bit line 114b, a second row 142b of the second plurality of rows 142 directly overlies the fourth bit line 114d, and so on. The second plurality of columns 144 individually underly alternating word lines (e.g., even numbered word lines counting sequentially from the first word line 116a) of the plurality of word lines 116. For example, a first column 144a of the second plurality of columns 144 directly overlies the second word line 116b, a second column 144b of the second plurality of columns 144 directly overlies the fourth word line 116d, and so on.

As shown in the top down view 100c of FIG. 1C, the read gate dielectric 120 of a first memory cell 146 surrounds the write transistor 102 and the read channel layer 118 in the second direction 128 and the third direction 130. The read gate dielectric 120 is surrounded by the second portion 122b of the interlayer dielectric 122. The read gate dielectric 120 of the first memory cell 146 is separated from a second read gate dielectric 147 of a second memory cell 148 by the second portion 122b of the interlayer dielectric 122. The separation of the read gate dielectric 120 of the first memory cell 146 from the second read gate dielectric 147 of the second memory cell 148 reduces coupling of a second write transistor 150 of the second memory cell 148 to the read channel layer 118 or other read channel layers (not shown) of surrounding memory cells. In some embodiments, the read gate dielectric 120 and the second read gate dielectric 147 have a square outer perimeter.

As shown in the top down view 100d of FIG. 1D, in some embodiments, the read gate dielectric 120 of the first memory cell 146 and other read gate dielectrics (e.g., the second read gate dielectric 147 and surrounding read gate dielectrics (not shown)) of other memory cells (e.g., the second memory cell 148 and surrounded memory cells (not shown)) have different profiles in the top down view to further reduce coupling between write transistors and read channel layers of different memory cells. For example, the cross-sectional profile of the read gate dielectrics 120, 147 shown in FIG. 1D have an increased thickness of the second portion 122b of the interlayer dielectric 122 between each other to further reduce coupling between the second write transistor 150 of the second memory cell 148 and the read channel layer 118 of the first memory cell 146. In some embodiments, the read gate dielectric 120 of the first memory cell 146 and other read gate dielectrics have a rectangular, polygonal, or other cross-sectional profile to further distance the read gate dielectric 120 from the other read gate dielectrics, while still extending from the write transistors of the memory cells to the corresponding read channel layers of the memory cells.

In general, FIGS. 1C-1D and the discussion herein illustrate a few of the many possibilities for cross-sectional profiles and configurations of the read gate dielectrics 120, 147, and do not represent a full complement of shapes that may be fabricated. The description of the read gate dielectrics 120, 147 herein is, therefore, not intended to be limiting. Those skilled in the art of semiconductor manufacturing will appreciate that variations of these shapes and other shapes may be easily fabricated to form differing cross-sectional profiles of the read gate dielectrics 120, 147 that conform to the definitions herein, and to serve a similar function.

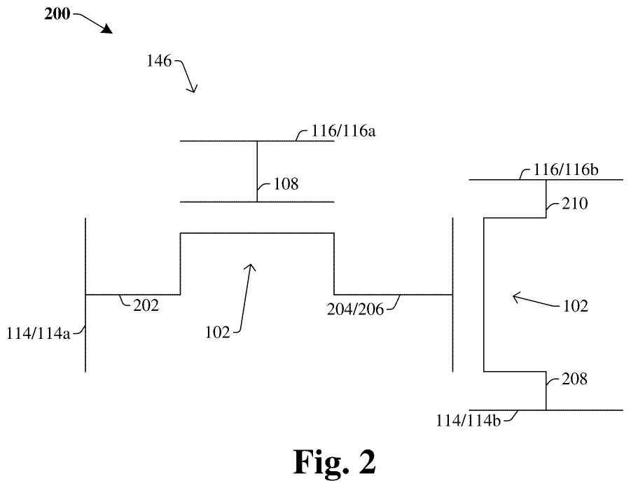

FIG. 2 illustrates a circuit diagram 200 of some embodiments of an integrated device having the memory cell with the two transistor architecture.

The first memory cell 146 comprises the write transistor 102 and the read transistor 104. The write transistor 102 comprises the write gate 108 coupled to the first word line 116a, a first source/drain region 202 coupled to the first bit line 114a, and a second source/drain region 204 coupled to a read gate 206 of the read transistor 104. The read transistor 104 comprises the read gate 206 coupled to the second source/drain region 204, a third source/drain region 208 coupled to the second bit line 114b, and a fourth source/drain region 210 coupled to the second word line 116b.

A “write” operation is used to set the charge held at the read gate 206 of the read transistor 104 to a “high” state (comprising a volume of charge resulting in a first current passing through of the read transistor 104) or a “low” state (comprising a volume of charge resulting in substantially zero current or a second current passing through of the read transistor 104, the second current being lower than the first current). A “write” operation is performed by driving the first bit line 114a to a first voltage (e.g., a predetermined voltage between approximately 0.5 volts and approximately 1.25 volts or within another similar range), then driving the first word line 116a to a voltage high enough to close the connection between the first source/drain region 202 and the second source/drain region 204 (e.g., over the threshold voltage of the write transistor 102, to a predetermined voltage between approximately 0.5 volts and approximately 1.5 volts or within another similar range). Connecting the first source/drain region 202 and the second source/drain region 204 results in the second source/drain region 204 and the read gate 206 to be driven to the first voltage. A corresponding first charge is driven to the read gate 206 based on the first voltage. The first word line 116a is subsequently driven to a voltage below the threshold voltage of the write transistor 102, trapping the charge at the read gate 206.

A “read” operation is used to determine the state (e.g., whether the state is the “high” state or the “low” state) of the data based on the charge held at the read gate 206. To perform a “read” operation, the first word line 116a is maintained at the voltage below the threshold, and the second word line 116b is driven to a high voltage (e.g., a predetermined voltage between approximately 0.5 volts and approximately 1.5 volts or within another similar range). If the charge held at the read gate 206 closes the connection between the third source/drain region 208 and the fourth source/drain region 210, a first current travels in the read channel layer 118 from the second word line 116b to the second bit line 114b, and it is determined that the memory cell holds the “high” state. If the charge held at the read gate 206 does not close the connection between the third source/drain region 208 and the fourth source/drain region 210, substantially zero current or a second current less than the first current travels through the read channel layer 118, and it is determined that the memory cell holds the “low” state.

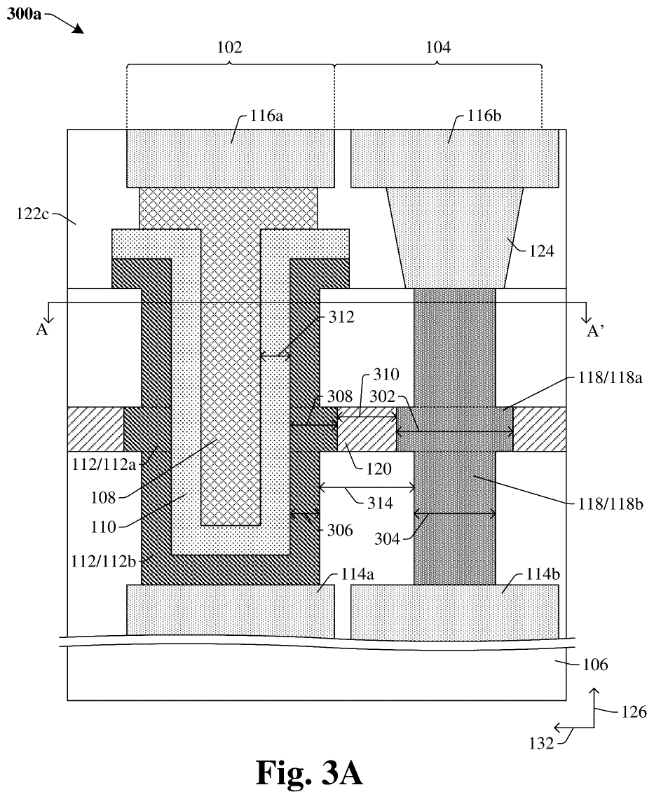

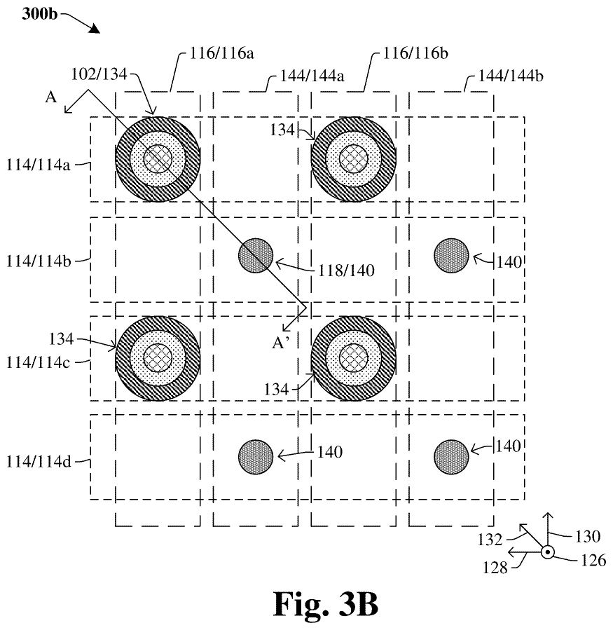

FIGS. 3A and 3B illustrate a cross-sectional view 300a and a top down view 300b of some embodiments of the integrated device having the memory cell with the two transistor architecture with bit lines and words lines of uniform widths. FIG. 3A is taken along line A-A′ of FIG. 3B.

In some embodiments, the write gate 108 has a longest dimension (e.g., a greatest length in one of the directions described in relation to FIG. 1B) in the first direction 126. The read channel layer 118 has a longest dimension in the first direction 126. In some embodiments, read gate dielectric 120 has a longest dimension in the fourth direction 132 and a shortest dimension (e.g., a lowest length in one of the directions described in relation to FIG. 1B) in the first direction 126.

The read channel layer 118 has a first portion 118a substantially level with the read gate dielectric 120 with a first thickness 302 in the fourth direction 132 and the second and third direction (see 128, 130 of FIG. 1B). Further, the read channel layer 118 has a second portion 118b substantially level with the first portion 122a of the interlayer dielectric 122 that has a second thickness 304 in the fourth direction 132 and the second and third direction (see 128, 130 of FIG. 1B). The first thickness 302 is greater than the second thickness 304.

The write channel layer 112 has a first portion 112a substantially level with the read gate dielectric 120 with a third thickness 306 in the fourth direction 132 and the second and third direction (see 128, 130 of FIG. 1B). Further, the write channel layer 112 has a second portion 112b substantially level with the first portion 122a of the interlayer dielectric 122 that has a fourth thickness 308 in the fourth direction 132 and the second and third direction (see 128, 130 of FIG. 1B). The third thickness 306 is greater than the fourth thickness 308. The second thickness 304 is equal to or greater than the third thickness 306.

The increased thickness of the first portions 112a, 118a of the write and read channel layers 112, 118 result from an etch resulting in the read gate dielectric 120 during the manufacturing process. The etch resulting in the read gate dielectric 120 determines the first minimum distance 310 (as discussed in relation to FIG. 1A and below), which can be chosen to optimize the read transistor 104 for reduced leakage between the read gate (see 206 of FIG. 2) and the read channel layer 118.

The read gate dielectric 120 has the first minimum distance 310 between the write channel layer 112 and the read channel layer 118. The write gate dielectric 110 has a fifth thickness 312 in the fourth direction 132 and the second and third direction (see 128, 130 of FIG. 1B). The first minimum distance 310 is equal to or greater than the fifth thickness 312. In some embodiments, a ratio of the thickness of the write gate dielectric 110 to the first minimum distance of the read gate dielectric 120 is 1, approximately 5, or a number between 1 and 5. In some embodiments, the first portion 122a of the interlayer dielectric 122 has a second minimum distance 314 between a first outer sidewall of the write channel layer 112 lined by the first portion 122a and a second outer sidewall of the read channel layer 118 lined by the first portion 122a is greater than the first minimum distance 310 between the write channel layer 112 and the read channel layer 118.

The differences in thickness available for the write channel layer 112 and the read channel layer 118, and the differences in thickness available for the write gate dielectric 110 and the read gate dielectric 120 both result in greater flexibility in the design of the write and read transistors 102, 104 compared to a 2T0C memory cell using planar transistors formed concurrently. For example, gate leakage current from the read transistor 104 is in part based on the first minimum distance 310 passing through the read gate dielectric 120, with a greater first minimum distance 310 resulting in lower gate leakage current. Further, a response time of the write transistor 102 is in part based on based on the fifth thickness 312 of the write gate dielectric 110, with a lower fifth thickness 312 improving the response time of the write transistor 102.

As shown in the top down view 300b of FIG. 3B, in some embodiments, the first bit line 114a and the second bit line 114b of the plurality of bit lines 114 have substantially the same width measured in the third direction 130. In some embodiments, the first word line 116a and the second word line 116b of the plurality of word lines 116 have substantially the same width measured in the second direction 128. In some embodiments, the plurality of bit lines 114 have a greater width measured in the third direction 130 than a width of the plurality of word lines 116 in the second direction 128.

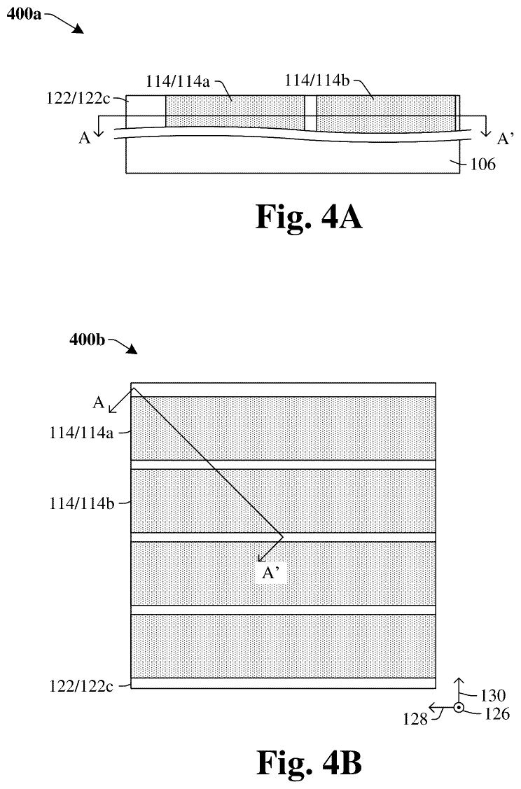

FIGS. 4A, 4B, 5A, 5B, 6A, 6B, 7A, 7B, 8A, 8B, 9A, 9B, 10A, 10B, 11A, 11B, 12A, 12B, 13A, 13B, 14, 15A, and 15B illustrate cross-sectional views 400a-1500a and top down views 400b-1500b of some embodiments of a method of forming an integrated device having the memory cell with the two transistor architecture. Although FIGS. 4A-15B are described in relation to a method, it will be appreciated that the structures disclosed in FIGS. 4A-15B are not limited to such a method, but instead may stand alone as structures independent of the method. Figures marked with “A” (e.g., FIGS. 4A, 5A, 6A . . . to 15A) are taken along lines A-A′ of corresponding figures marked with “B” (e.g., FIGS. 4B, 5B, 6B . . . to 15B). Figures marked with “A” are described concurrently with the corresponding figures marked with “B”.

As shown in cross-sectional view 400a and top down view 400b of FIGS. 4A and 4B, the plurality of bit lines 114 are formed over the substrate 106. The plurality of bit lines 114 are separated from each other in the third direction 130 and extend substantially parallel to each other in the second direction. In some embodiments, the plurality of bit lines 114 have substantially equal widths. In other embodiments, the plurality of bit lines 114 alternate between having a first width and a second width (see FIG. 1B), where the second width is less than the first width.

In some embodiments, the plurality of bit lines 114 are formed by a combination of etching an underlying portion 122d of the interlayer dielectric 122 to form openings, depositing a conformal conductive layer in the openings, then performing a planarization process (e.g., a chemical mechanical planarization (CMP) process) to remove portions of the conformal conductive layer extending across a top surface of the underlying portion 122d. In other embodiments, the plurality of bit lines 114 are formed using a different combination of etching and deposition processes, a damascene process, a dual damascene process, or the like. In some embodiments, the plurality of bit lines 114 are or comprise a conductive material, such as such as copper (Cu), tungsten (W), aluminum (Al), or the like. In some embodiments, the underlying portion 122d of the interlayer dielectric 122 are or comprise an insulative material such as silicon dioxide (SiO₂) or the like.

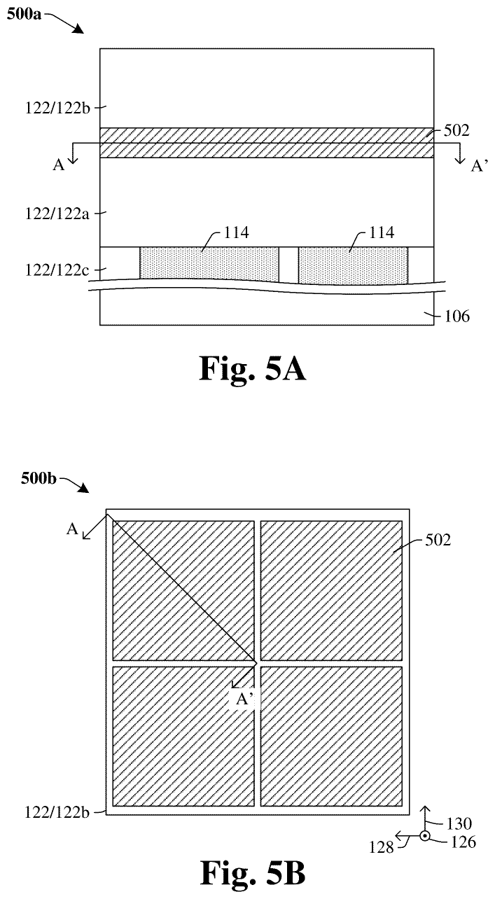

As shown in cross-sectional view 500a and top down view 500b of FIGS. 5A and 5B, the first portion 122a of the interlayer dielectric 122, a first conformal dielectric 502, and the second portion 122b of the interlayer dielectric 122 are formed over the plurality of bit lines 114. The first conformal dielectric 502 is etched to separate a plurality of portions of the first conformal dielectric 502 corresponding to different memory cells of the memory cell array before the second portion 122b is formed. In some embodiments, the first conformal dielectric 502 is etched by forming a masking layer (not shown) over the first conformal dielectric 502, patterning the masking layer to expose portions of the first conformal dielectric 502 corresponding to the spaces between memory cells, and performing an anisotropic dry etching process to remove the portions of the first conformal dielectric 502 corresponding to the spaces between memory cells.

As described in relation to in FIGS. 1C and 1D, the pattern of the first conformal dielectric 502 after etching may comprise a variety of different cross-sectional shapes, provided portions of the first conformal dielectric 502 extending from the write transistors (see 102 of FIGS. 1C, 1D) to the corresponding read channel layers (see 118 of FIGS. 1C, 1D) of the plurality of memory cells to be formed hereafter are maintained to function as the read gate dielectric (see 120 of FIGS. 1C, 1D).

In some embodiments, the first portion 122a of the interlayer dielectric 122, a first conformal dielectric 502, and the second portion 122b of the interlayer dielectric 122 are independently formed using one or more deposition processes, such as atomic layer deposition (ALD), physical vapor deposition (PVD), chemical vapor deposition (CVD), or the like. In some embodiments, the first portion 122a and the second portion 122b of the interlayer dielectric 122 are or comprise an insulative material such as silicon dioxide (SiO₂) or the like. In some embodiments, the first conformal dielectric 502 is or comprises a dielectric material such as titanium oxide (TiO₂), aluminum oxide (Al₂O₃), zirconium oxide (ZrO₂), hafnium oxide (HfO₂), hafnium titanate (HfTiO₄ or a material with another ratio of hafnium, titanium, and oxygen), lanthanum hafnate (HfLaO or a material with another ratio of hafnium, lanthanum, and oxygen), hafnium silicate (HfSiO₄ or a material with another ratio of hafnium, silicon, and oxygen), hafnium zirconium oxide (HZO or a material with another ratio of hafnium, zirconium, and oxygen), or another similar material.

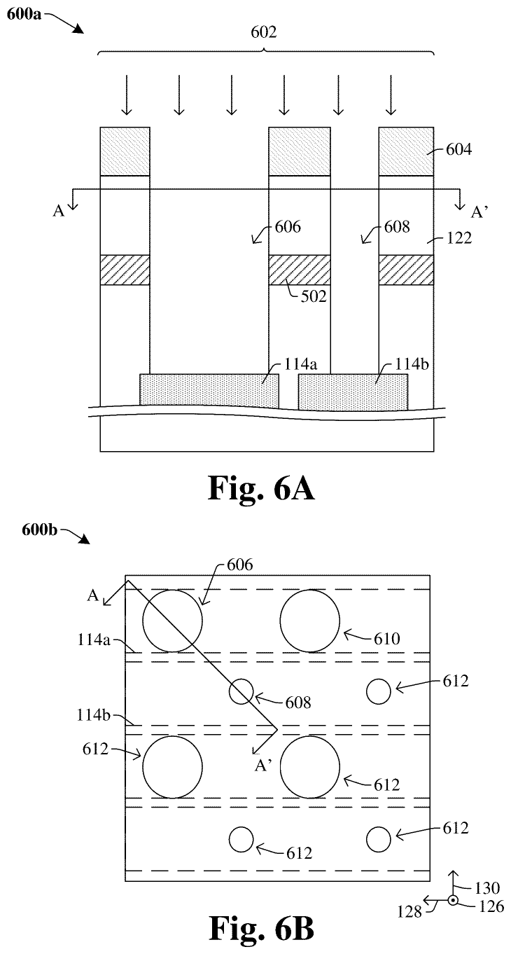

As shown in cross-sectional view 600a and top down view 600b of FIGS. 6A and 6B, a first masking layer 604 is formed over the interlayer dielectric 122. In some embodiments, the first masking layer 604 is or comprises a photoresist or a hard mask and is formed using a dipping process, spin on process, deposition process, or another similar process. The first masking layer 604 is then patterned. In some embodiments, the first masking layer 604 is patterned using photolithography. The patterning of the first masking layer 604 is performed to expose portions of the interlayer dielectric 122 corresponding to positions of the write transistor (see 102 of FIGS. 1A-1D) and the read channel layer (see 118 of FIGS. 1A-1D).

After the patterning of the first masking layer 604, a first etching process 602 is performed. The first etching process 602 removes portions of the interlayer dielectric 122 and the first conformal dielectric 502 corresponding to the positions of the write transistor (see 102 of FIGS. 1A-1D) and the read channel layer (see 118 of FIGS. 1A-1D), exposing a first bit line 114a and a second bit line 114b. In some embodiments, the first etching process 602 further removes portions of the interlayer dielectric 122 and the first conformal dielectric 502 corresponding to the positions of write transistor and read channel layers of the array of write transistors (see 134 of FIGS. 1B, 3B) and the array of read channel layers (see 140 of FIGS. 1B, 3B), resulting in the third opening 610 and other additional openings 612. In some embodiments, the first etching process 602 is or comprises an anisotropic dry etching process. The first masking layer 604 is subsequently removed.

The first etching process 602 results in a first opening 606 and a second opening 608 remaining over the first bit line 114a and the second bit line 114b, respectively. The first opening 606 has a greater width than the second opening. In some embodiments, a ratio between the widths of the first opening and the second opening is approximately 1.5, approximately 10, or between 1.5 and 10. In some embodiments, a ratio between the width of the first opening and the depth of the first opening is 1, approximately 50, or between 1 and 50. The widths of the first opening 606 and the second opening 608 are selected based on the desired thicknesses of the write channel layer (see 112 of FIG. 1A) and the read channel layer (see 118 of FIG. 1A) to be formed hereafter. The distance between the first opening 606 and the second opening 608 is selected based on the desired thickness of the read gate dielectric (see 120 of FIG. 1A) to be formed hereafter.

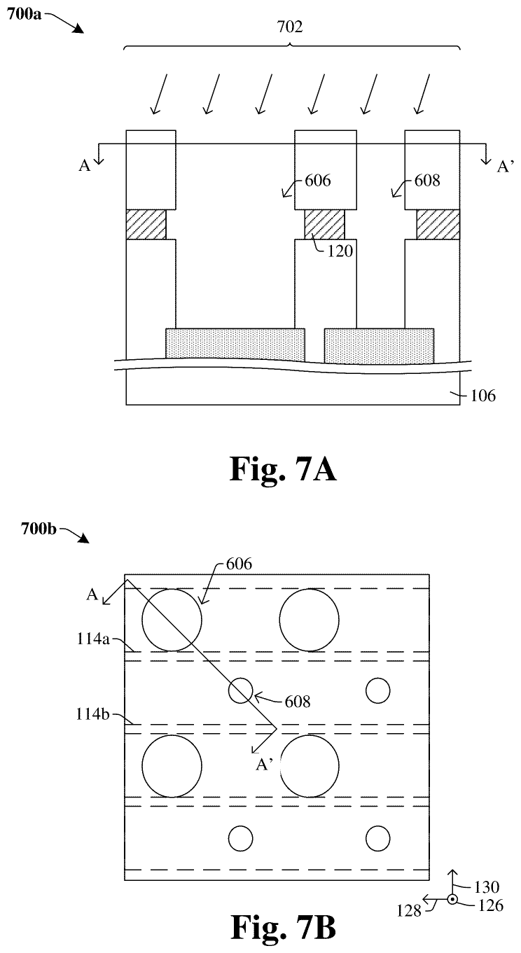

As shown in cross-sectional view 700a and top down view 700b of FIGS. 7A and 7B, a first isotropic etching process 702 is performed. The first isotropic etching process 702 is selective, and removes portions of the first conformal dielectric (see 502 FIG. 6A) exposed by the first and second openings 606, 608. The first isotropic etching process 702 results in portions of the first conformal dielectric (see 502 FIG. 6A) being removed, and the read gate dielectric 120 remaining over the substrate 106. The first isotropic etching process 702 is performed to tune the thickness of the read gate dielectric 120 to improve performance of the read transistor (see 104 of FIG. 1A) to be formed hereafter.

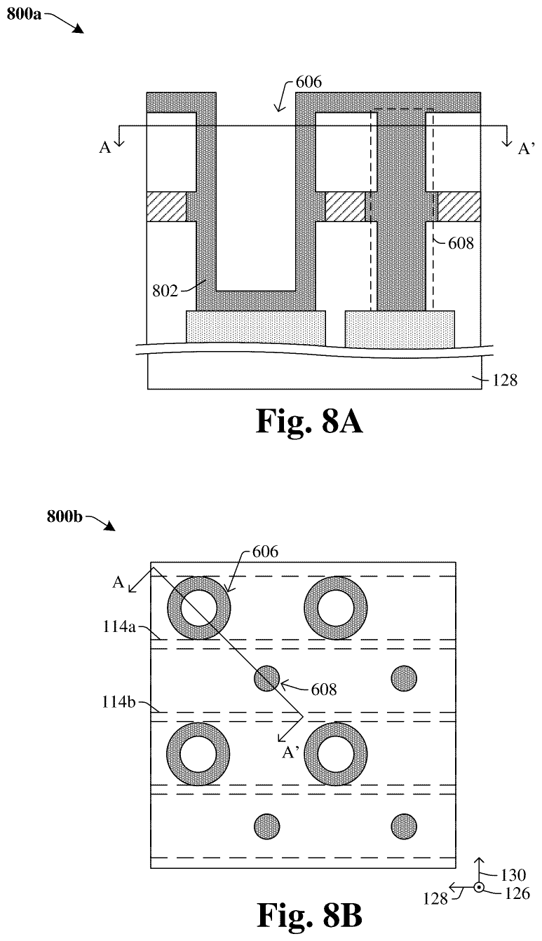

As shown in cross-sectional view 800a and top down view 800b of FIGS. 8A and 8B, a conformal channel layer 802 is formed over the first opening 606 and fills the second opening 608 (shown in phantom). Due to the difference between the widths of the first opening 606 and the second opening 608, the portions of the conformal channel layer 802 in the first opening 606 have a first thickness, and portions of the conformal channel layer 802 in the second opening 608 have a second thickness. In some embodiments, a ratio of the second thickness to the first thickness is 1, approximately 3, or a number between 1 and 3.

In some embodiments, the conformal channel layer 802 is formed using a deposition processes, such as ALD, PVD, CVD, or the like. In some embodiments, the conformal channel layer 802 is or comprises a semiconductor material, such as (InₓGa_{y}Zn_{z}MO), where M can be titanium (Ti), aluminum (Al), silver (Ag), tungsten (W), cerium (Ce), tin (Sn), vanadium (V), scandium (Sc), and x, y, and z are between 0 and 1, or another oxide semiconductor material.

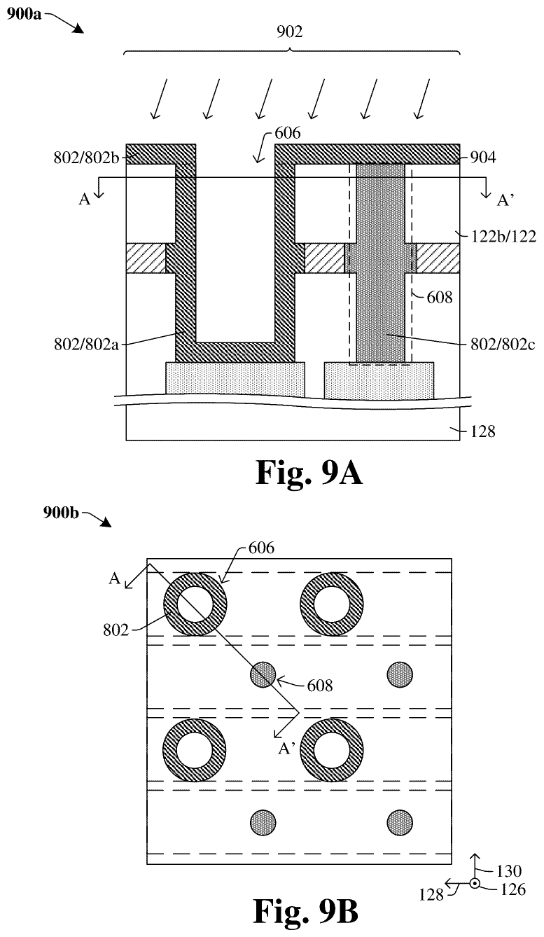

As shown in cross-sectional view 900a and top down view 900b of FIGS. 9A and 9B, an oxygen treatment 902 is performed on the conformal channel layer 802. In some embodiments, the oxygen treatment 902 is an oxidation treatment using a gas, plasma, or the like to increase the oxygen density of exposed portions of the conformal channel layer. The exposed portions of the conformal channel layer 802 including a portion 802a of the conformal channel layer 802 within the first opening 606 and portions 802b of the conformal channel layer overlying a first surface 904 of the second portion 122b of the interlayer dielectric 122. The portion 802c of the conformal channel layer 802 within the second opening 608 is insulated from the oxygen treatment 902 by the portions 802b of the conformal channel layer 802 overlying the second portion 122b of the interlayer dielectric 122.

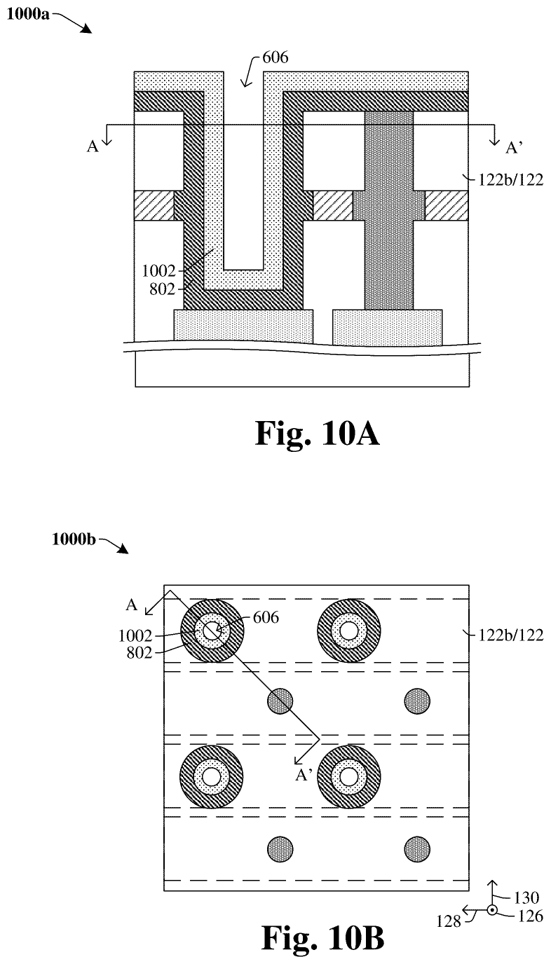

As shown in cross-sectional view 1000a and top down view 1000b of FIGS. 10A and 10B, a second conformal dielectric 1002 is formed in the first opening 606 and over the second portion 122b of the interlayer dielectric 122. In some embodiments, the second conformal dielectric 1002 is formed using a deposition processes, such as ALD, PVD, CVD, or the like. In some embodiments, the second conformal dielectric 1002 is or comprises a dielectric material such as titanium oxide (TiO₂), aluminum oxide (Al₂O₃), zirconium oxide (ZrO₂), hafnium oxide (HfO₂), hafnium titanate (HfTiO₄ or a material with another ratio of hafnium, titanium, and oxygen), lanthanum hafnate (HfLaO or a material with another ratio of hafnium, lanthanum, and oxygen), hafnium silicate (HfSiO₄ or a material with another ratio of hafnium, silicon, and oxygen), hafnium zirconium oxide (HZO or a material with another ratio of hafnium, zirconium, and oxygen), or another similar material.

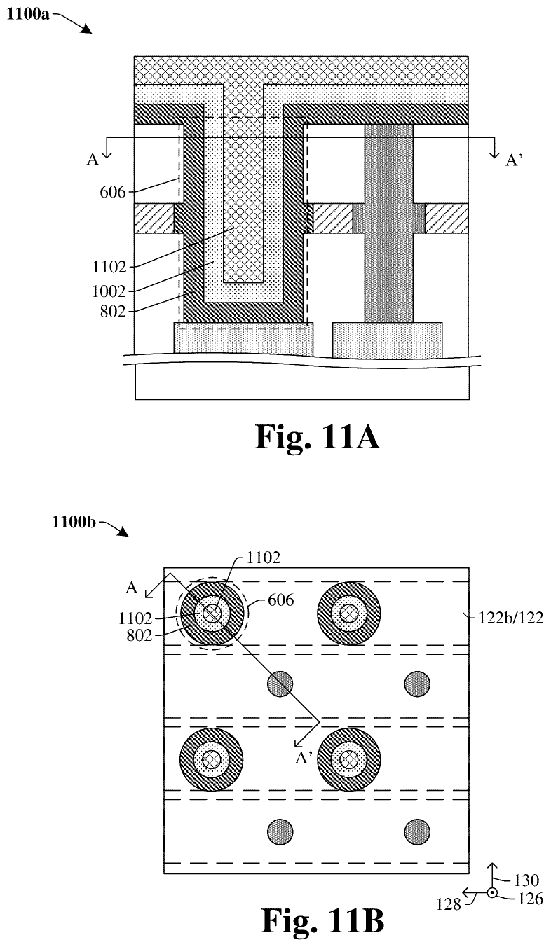

As shown in cross-sectional view 1100a and top down view 1100b of FIGS. 11A and 11B, a conformal gate layer 1102 is formed, filling the first opening 606 (shown in phantom). In some embodiments, the conformal gate layer 1102 is formed using a deposition process, such as ALD, PVD, CVD, or the like. In some embodiments, the conformal gate layer 1102 is or comprises a conductive material, such as copper (Cu), tungsten (W), aluminum (Al), or the like.

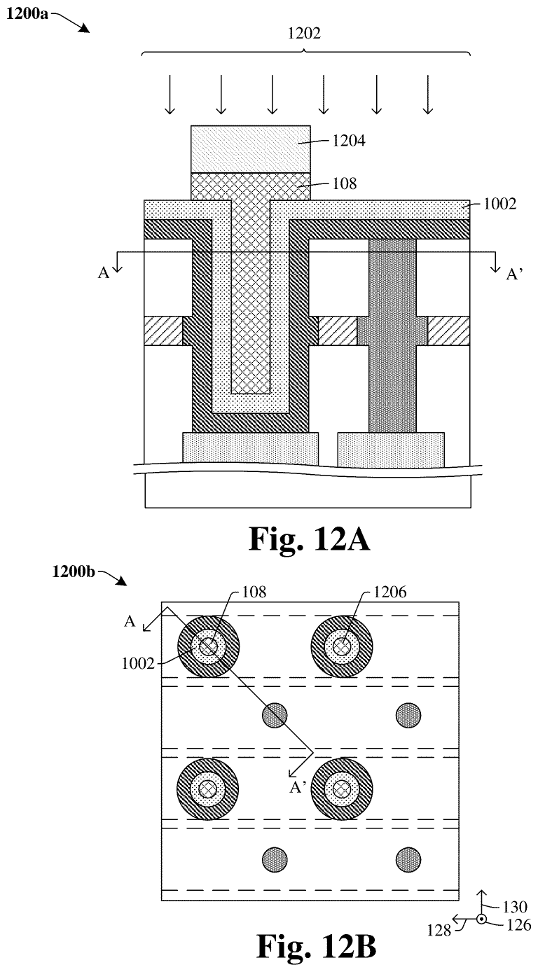

As shown in cross-sectional view 1200a and top down view 1200b of FIGS. 12A and 12B, a second masking layer 1204 is formed over the conformal gate layer (see 1102 of FIG. 11A). In some embodiments, the second masking layer 1204 is or comprises a photoresist or a hard mask and is formed using a dipping process, spin on process, deposition process, or another similar process. The second masking layer 1204 is then patterned. In some embodiments, the second masking layer 1204 is patterned using photolithography. The patterning of the second masking layer 1204 is performed to expose portions of the conformal gate layer (see 1102 of FIG. 11A) surrounding the write gate 108 to be formed hereafter.

After the patterning of the second masking layer 1204, a second etching process 1202 is performed. The second etching process 1202 removes portions of the conformal gate layer (see 1102 of FIG. 11A) exposed by the patterning of the second masking layer 1204, resulting in the write gate 108 remaining on the second conformal dielectric 1002. In some embodiments, etching the conformal gate layer (see 1102 of FIG. 11A) results in a second write gate 1206 remaining in the third opening (see 610 of FIG. 6B), with the second write gate 1206 being electrically isolated from the write gate 108. In some embodiments, the second etching process 1202 is or comprises an anisotropic dry etching process. The second masking layer 1204 is subsequently removed.

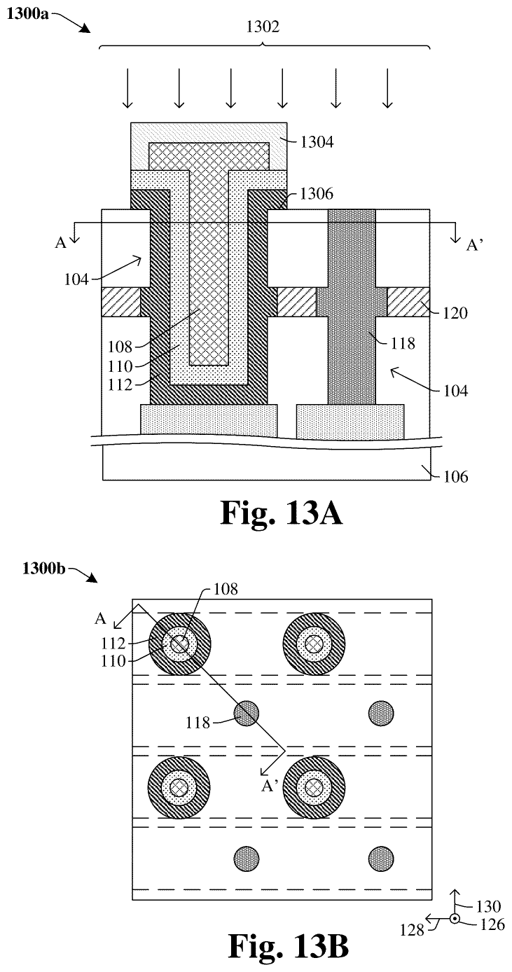

As shown in cross-sectional view 1300a and top down view 1300b of FIGS. 13A and 13B, a third masking layer 1304 is formed over the write gate 108 and the second conformal dielectric (see 1002 of FIG. 10A). In some embodiments, the third masking layer 1304 is or comprises a photoresist or a hard mask and is formed using a dipping process, spin on process, deposition process, or another similar process. The third masking layer 1304 is then patterned. In some embodiments, the third masking layer 1304 is patterned using photolithography. The patterning of the third masking layer 1304 is performed to expose portions of the second conformal dielectric (see 1002 of FIG. 10A) surrounding the write gate dielectric 110 and the write channel layer 112 to be formed hereafter.

After the patterning of the third masking layer 1304, a third etching process 1302 is performed. The third etching process 1302 removes portions of the second conformal dielectric (see 1002 of FIG. 10A) and the conformal channel layer (see 802 of FIG. 8A) exposed by the patterning of the third masking layer 1304, resulting in the write gate dielectric 110 and the write channel layer 112 remaining in the first opening 606 (shown in phantom) and extending out of the first opening 606, as well as the read channel layer 118 separated from the write channel layer 112 and in the second opening 608 (shown in phantom). The third etching process 1302 results in the components of the write transistor 102 and the read transistor 104 remaining on the substrate 106. Further, after the third etching process 1302, a lower surface 1306 of the write channel layer 112 remains over an upper surface of the read gate dielectric 120. In some embodiments, the third etching process 1302 is or comprises an anisotropic dry etching process. The third masking layer 1304 is subsequently removed.

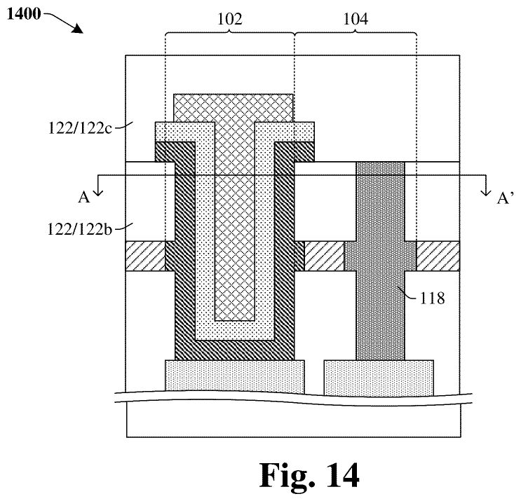

As shown in cross-sectional view 1400 FIG. 14, a third portion 122c of the interlayer dielectric 122 is formed, covering the write transistor 102, the read transistor 104, and the second portion 122b of the interlayer dielectric 122. In some embodiments, the third portion 122c is formed using a deposition process, such as ALD, PVD, CVD, or the like. In some embodiments, the third portion 122c is or comprises an insulative material, such as silicon dioxide (SiO₂) or the like.

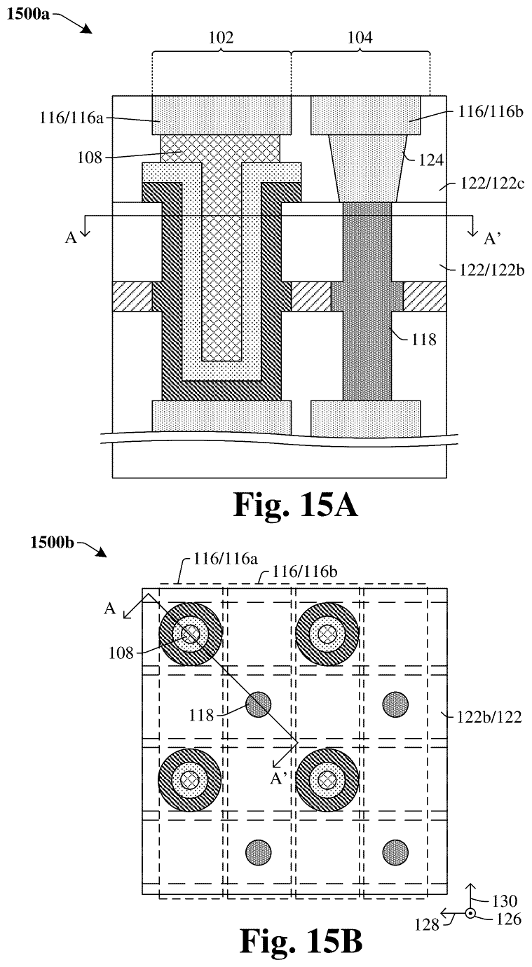

As shown in cross-sectional view 1500a and the top down view 1500b of FIGS. 15A and 15B, the first word line 116a, the via 124, and the second word line 116b are formed, such that the first word line 116a is coupled to the write gate 108 and the second word line 116b is coupled to the read channel layer 118 by the via 124. In some embodiments, first word line 116a, the via 124, and the second word line 116b are formed using a damascene process, a dual damascene process, or the like. In some embodiments, the first word line 116a and the second word line 116b is or comprises an insulative material, such as copper (Cu), tungsten (W), aluminum (Al) or the like.

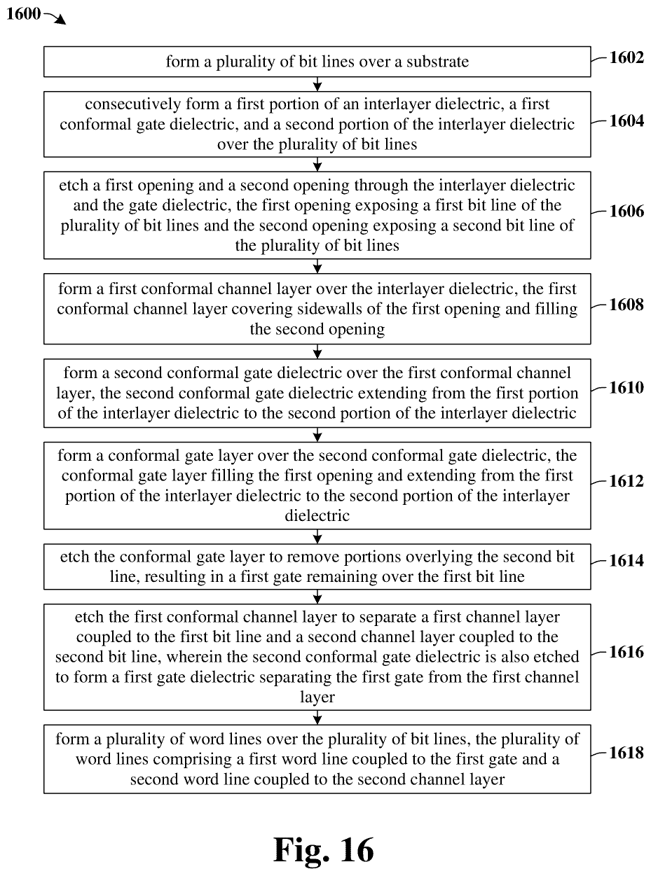

FIG. 16 illustrates a flow diagram 1600 of some embodiments of a method of forming an integrated device having the memory cell with the two transistor architecture. While method 1600 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At 1602, a plurality of bit lines are formed over a substrate. FIG. 4A illustrates a cross-sectional view 400a of some embodiments corresponding to act 1602.

At 1604, a first portion of an interlayer dielectric, a first conformal gate dielectric, and a second portion of the interlayer dielectric are consecutively formed over the plurality of bit lines. FIG. 5A illustrates a cross-sectional view 500a of some embodiments corresponding to act 1604.

At 1606, a first opening and a second opening are etched through the interlayer dielectric and the gate dielectric, the first opening exposing a first bit line of the plurality of bit lines and the second opening exposing a second bit line of the plurality of bit lines. FIG. 6A illustrates a cross-sectional view 600a of some embodiments corresponding to act 1606.

At 1608, a first conformal channel layer is formed over the interlayer dielectric, the first conformal channel layer covering sidewalls of the first opening and filling the second opening. FIG. 8A illustrates a cross-sectional view 800a of some embodiments corresponding to act 1608.

At 1610, a second conformal gate dielectric is formed over the first conformal channel layer, the second conformal gate dielectric extending from the first portion of the interlayer dielectric to the second portion of the interlayer dielectric. FIG. 10A illustrates a cross-sectional view 1000a of some embodiments corresponding to act 1610.

At 1612, a conformal gate layer is formed over the second conformal gate dielectric, the conformal gate layer filling the first opening and extending from the first portion of the interlayer dielectric to the second portion of the interlayer dielectric. FIG. 11A illustrates a cross-sectional view 1100a of some embodiments corresponding to act 1612.

At 1614, the conformal gate layer is etched to remove portions overlying the second bit line, resulting in a write gate remaining over the first bit line. FIG. 12A illustrates a cross-sectional view 1200a of some embodiments corresponding to act 1614.

At 1616, the first conformal channel layer is etched to separate a write channel layer coupled to the first bit line and a read channel layer coupled to the second bit line, wherein the second conformal gate dielectric is also etched to form a write gate dielectric separating the write gate from the write channel layer. FIG. 13A illustrates a cross-sectional view 1300a of some embodiments corresponding to act 1616.

At 1618, a plurality of word lines are formed over the plurality of bit lines, the plurality of word lines comprising a first word line coupled to the write gate and a second word line coupled to the read channel layer. FIG. 15A illustrates a cross-sectional view 1500a of some embodiments corresponding to act 1618.

Accordingly, in some embodiments, the present disclosure relates to an integrated device, including: a write gate over a substrate having a longest dimension in a first direction normal to a surface of the substrate; a write gate dielectric surrounding outer sidewalls of the write gate; a write channel layer surrounding outer sidewalls of the write gate dielectric; a read gate dielectric having a shortest dimension in the first direction and surrounding the write channel layer in a second direction and a third direction, the second direction and the third direction being perpendicular to the first direction; and a read channel layer having a longest dimension in the first direction, wherein a shortest path between the write channel layer and the read channel layer extends through the read gate dielectric.

In other embodiments, the present disclosure relates to a method of forming an integrated device, including: forming a plurality of bit lines over a substrate; forming a first portion of an interlayer dielectric, a first conformal gate dielectric, and a second portion of the interlayer dielectric over the plurality of bit lines; etching a first opening and a second opening through the interlayer dielectric and the first conformal gate dielectric, the first opening exposing a first bit line of the plurality of bit lines and the second opening exposing a second bit line of the plurality of bit lines; forming a first conformal channel layer over the interlayer dielectric, the first conformal channel layer covering sidewalls of the first opening and filling the second opening; forming a second conformal gate dielectric over the first conformal channel layer, the second conformal gate dielectric extending from the first portion of the interlayer dielectric to the second portion of the interlayer dielectric; forming a conformal gate layer over the second conformal gate dielectric, the conformal gate layer filling the first opening and extending from the first portion of the interlayer dielectric to the second portion of the interlayer dielectric; etching the conformal gate layer to remove portions overlying the second bit line, resulting in a write gate remaining over the first bit line; etching the first conformal channel layer to separate a write channel layer coupled to the first bit line and a read channel layer coupled to the second bit line, wherein the second conformal gate dielectric is also etched to form a write gate dielectric separating the write gate from the write channel layer; and forming a plurality of word lines over the plurality of bit lines, the plurality of word lines including a first word line coupled to the write gate and a second word line coupled to the read channel layer.

In yet other embodiments, the present disclosure relates to a method of forming an integrated device, including: forming a first conformal gate dielectric over a plurality of bit lines, the first conformal gate dielectric being separated from the plurality of bit lines by a first portion of an interlayer dielectric; etching a first opening and a second opening extending through the first conformal gate dielectric to the plurality of bit lines, the first opening having a first width and exposing a first bit line of the plurality of bit lines, and the second opening having a second width less than the first width and exposing a second bit line of the plurality of bit lines; performing a first isotropic etching process to remove portions of the first conformal gate dielectric extending directly between the first opening and the second opening; forming a first conformal channel layer over the plurality of bit lines, the first conformal channel layer covering sidewalls of the first opening and filling the second opening; performing an oxygen treatment to increase an oxygen density in exposed portions of the first conformal channel layer; forming a write gate dielectric and a gate in the first opening; and removing a portion of the first conformal channel layer exposed to the oxygen treatment and overlying the second bit line, resulting in a write channel layer with a first oxygen density remaining in the first opening and a read channel layer with a second oxygen density remaining in the second opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a write gate over a substrate having a longest dimension in a first direction normal to a surface of the substrate;
a write gate dielectric surrounding outer sidewalls of the write gate;
a write channel layer surrounding outer sidewalls of the write gate dielectric;
a read gate dielectric having a shortest dimension in the first direction and surrounding the write channel layer in a second direction and a third direction, the second direction and the third direction being perpendicular to the first direction; and
a read channel layer having a longest dimension in the first direction, wherein a shortest path between the write channel layer and the read channel layer extends through the read gate dielectric.

2. The integrated device of claim 1, further comprising:
a first bit line extending in the second direction and beneath the write gate, the first bit line being coupled to the write channel layer;
a first word line extending in the third direction and over the write gate, the first bit line being coupled to the write gate;
a second bit line extending substantially parallel to the first bit line and coupled to the read channel layer; and
a second word line extending substantially parallel to the first word line and coupled to the read channel layer.

3. The integrated device of claim 1, further comprising a first portion of an interlayer dielectric beneath the read gate dielectric, wherein a first distance between a first outer sidewall of the write channel layer lined by the first portion and a second outer sidewall of the read channel layer lined by the first portion is greater than a first minimum distance between the write channel layer and the read channel layer.

4. The integrated device of claim 3, wherein a first portion of the read channel layer substantially level with the read gate dielectric has a first thickness in the second and third direction, and a second portion of the read channel layer substantially level with the first portion of the interlayer dielectric has a second thickness in the second and third direction, and wherein the first thickness is greater than the second thickness.

5. The integrated device of claim 3, further comprising a second portion of the interlayer dielectric above the read gate dielectric, wherein the second portion of the interlayer dielectric surrounds the read gate dielectric in the second direction and the third direction.

6. The integrated device of claim 5, wherein the second portion of the interlayer dielectric extends to the first portion of the interlayer dielectric.

7. The integrated device of claim 1, wherein the write channel layer has a first oxygen density, the read channel layer has a second oxygen density, and the first oxygen density is greater than the second oxygen density.

8. The integrated device of claim 1, wherein the write channel layer has a first thickness, the read channel layer has a second thickness, and the first thickness is less than the second thickness.

9. A method of forming an integrated device, comprising:
forming a plurality of bit lines over a substrate;
forming a first portion of an interlayer dielectric, a first conformal gate dielectric, and a second portion of the interlayer dielectric over the plurality of bit lines;
etching a first opening and a second opening through the interlayer dielectric and the first conformal gate dielectric, the first opening exposing a first bit line of the plurality of bit lines and the second opening exposing a second bit line of the plurality of bit lines;
forming a first conformal channel layer over the interlayer dielectric, the first conformal channel layer covering sidewalls of the first opening and filling the second opening;
forming a second conformal gate dielectric over the first conformal channel layer, the second conformal gate dielectric extending from the first portion of the interlayer dielectric to the second portion of the interlayer dielectric;
forming a conformal gate layer over the second conformal gate dielectric, the conformal gate layer filling the first opening and extending from the first portion of the interlayer dielectric to the second portion of the interlayer dielectric;
etching the conformal gate layer to remove portions overlying the second bit line, resulting in a write gate remaining over the first bit line;
etching the first conformal channel layer to separate a write channel layer coupled to the first bit line and a read channel layer coupled to the second bit line, wherein the second conformal gate dielectric is also etched to form a write gate dielectric separating the write gate from the write channel layer; and
forming a plurality of word lines over the plurality of bit lines, the plurality of word lines comprising a first word line coupled to the write gate and a second word line coupled to the read channel layer.

10. The method of claim 9, further comprising performing a first isotropic etching process to remove portions of the first conformal gate dielectric surrounding the first opening and the second opening, lowering a distance of a shortest path between the first opening and the second opening and resulting in a read gate dielectric remaining between the first opening and the second opening.

11. The method of claim 10, wherein a third opening is formed concurrent with forming the first opening, the third opening being directly over the first bit line;
wherein forming the conformal gate layer results in the conformal gate layer extending inti the third opening; and
wherein etching the conformal gate layer results in a second write gate remaining in the third opening, the read gate electrically isolated from the write gate.

12. The method of claim 9, further comprising performing an oxidation treatment on the first conformal channel layer to increase an oxygen density of exposed portions of the first conformal channel layer.

13. The method of claim 12, wherein after the oxidation treatment, a portion of the first conformal channel layer directly overlying the second bit line has a first oxygen density, and wherein the etching of the first conformal channel layer removes the portion of the first conformal channel layer directly overlying the second bit line with the first oxygen density.

14. The method of claim 9, wherein the read channel layer extends between the second bit line and the second word line in a first direction, and the read channel layer is separated from the write channel layer in a direction approximately midway between a second direction and a third direction, where the second direction and the third direction are approximately perpendicular to each other and to the first direction.

15. A method of forming an integrated device, comprising:
forming a first conformal gate dielectric over a plurality of bit lines, the first conformal gate dielectric being separated from the plurality of bit lines by a first portion of an interlayer dielectric;
etching a first opening and a second opening extending through the first conformal gate dielectric to the plurality of bit lines, the first opening having a first width and exposing a first bit line of the plurality of bit lines, and the second opening having a second width less than the first width and exposing a second bit line of the plurality of bit lines;
performing a first isotropic etching process to remove portions of the first conformal gate dielectric extending directly between the first opening and the second opening;
forming a first conformal channel layer over the plurality of bit lines, the first conformal channel layer covering sidewalls of the first opening and filling the second opening;
performing an oxygen treatment to increase an oxygen density in exposed portions of the first conformal channel layer;
forming a write gate dielectric and a first gate in the first opening; and
removing a portion of the first conformal channel layer exposed to the oxygen treatment and overlying the second bit line, resulting in a write channel layer with a first oxygen density remaining in the first opening and a read channel layer with a second oxygen density remaining in the second opening.

16. The method of claim 15, further comprising:
forming a first plurality of openings concurrent with forming the first opening, the first plurality of openings exposing the first bit line and having approximately a same width as the first width, wherein the first plurality of openings extend in a first direction and the plurality of bit lines extend in a second direction perpendicular to the first direction;
forming a second plurality of openings concurrent with forming the second opening, the second plurality of openings exposing the second bit line and having approximately a same width as the second width, wherein the second plurality of openings are spaced from each other in the second direction; and
forming a plurality of word lines extending in a third direction approximately perpendicular to the second direction, wherein odd numbered word lines of the plurality of word lines individually extend directly over the first opening or an opening of the first plurality of openings, and even numbered word lines of the plurality of word lines individually extend directly over either the second opening or the second plurality of openings.

17. The method of claim 15, further comprising forming a second portion of the interlayer dielectric after forming the first conformal gate dielectric, wherein the first opening and the second opening are etched through the second portion of the interlayer dielectric.

18. The method of claim 15, wherein after the first isotropic etching process, a read gate dielectric remains between the first opening and the second opening, and wherein after removing the portion of the first conformal channel layer, a lower surface of the write channel layer extends directly over an upper surface of the read gate dielectric.

19. The method of claim 15, wherein the plurality of bit lines are formed over a substrate, wherein the first opening extends in a first direction approximately normal to a surface of the substrate, wherein the plurality of bit lines extend in a second direction perpendicular to the first direction.

20. The method of claim 15, wherein removing a portion of the first conformal channel layer comprises performing an etching process.
